(19) United States
(12) Patent Application Publication
(10) Pub. No.: US 2006/0202688 A1
(43) Pub. Date: Sep. 14, 2006

(54) Detection system and method thereof

(76) Inventors: Kirby Dean Woods, Omaha, NE (US); Steven Grant Price, Sycamore, IL (US); Kenneth Mark Williamson, Rockford, IL (US); Gary Lane Burkhardt, Adkins, TX (US)

Correspondence Address: NIXON PEABODY LLP - PATENT GROUP, CLINTON SQUARE, P.O. BOX 31051, ROCHESTER, NY, 14603-1051, US

(21) Appl. No.: 11/290,846

(22) Filed: Dec. 1, 2005

Related U.S. Application Data
(60) Provisional application No. 60/631,869, filed on Dec. 1, 2004.

(51) Int. Cl. G01R 33/12

(52) U.S. Cl. 324/239

(57) ABSTRACT

A detection system including an eddy current inducing unit; at least one magnetic field data sensor electrically coupled to a biasing unit, wherein the biasing unit is adapted to maintain the at least one magnetic field data sensor within a predetermined operating range when applied to selected locations of a workpiece as a function of residual magnetic field of the workpiece; and a scanner to position the at least one magnetic field data sensor at the selected locations on the workpiece at various resolutions is disclosed. Methods for identifying an area of interest in a material are also disclosed.

This application claims the benefit of U.S. Provisional Patent Application No. 60/631,869 filed on Dec. 1, 2004, which is hereby incorporated by reference for all purposes as if fully set forth herein.

### BACKGROUND OF THE INVENTION

1. Field of the Invention

The invention relates generally to a detection system and method for non-invasive inspection of electrically conductive and ferromagnetic materials. More specifically, the invention relates to inspection of various geometries of electrically conductive and ferromagnetic materials.

2. Discussion of the Related Art

Conventional eddy current detection systems are being utilized to determine flaws in various electrically conductive or ferromagnetic materials. Conventional eddy current detection systems include various probes, such as, absolute probes, differential probes, and driver-pickup/reflection probes as known in the art. Conventional eddy current testing is an electromagnetic nondestructive inspection where the specimen's conductivity is the predominate variable of interest affecting the system's output signal. With this testing method, eddy current flow is induced in the test object using a driver coil. Changes in the flow caused by variations in the specimen reflect into a receiving or pick-up coil, coils, or Hall Effect instrument for subsequent analysis by suitable instrumentation and techniques. These changes are considered flaw signals. An eddy current flaw signal is a unique signature with the appearance of a hook which suggests a surface break or linear discontinuity in a high electrically conductive material. One side of the signature hook is typically the lift-off-line. The hook's included angle is the separation angle.

Absolute probes use a single test coil that is very sensitive to conductivity changes and geometric changes. There are a number of disadvantages to using this probe, for example, the absolute probes cannot go from one material to another without recalibration and minimal to no change is observed to gradual changes in a flaw.

Differential probes use two coils wound in opposite directions as known in the art. In operation, when one coil is over a flaw and the other coil is over good material the difference between the impedance values in the two coils is indicated a flaw to the user. There are number of disadvantages to using this type of probe. For example, when the flaw is longer than the spacing between the two coils only the ends of the flaw will be picked up and recorded.

Driver-pickup/reflection probes use two coils as known in the art. One coil induces current and the other coil senses the change in the induced current. There are a number of disadvantages to using this type of probe. These probes are normally highly sensitive to cracks that are parallel to a primary axis of sensitivity of the probe. This type of sensor arrangement experiences greatly reduced sensitivity to cracks which lie out of line with the primary axis of sensitivity. In addition, for accurate measurements of flaws lift-off is a problem with this probe.

### SUMMARY OF THE INVENTION

The present invention is directed to a detection system and method thereof that substantially obviates one or more of the problems due to limitations and disadvantages of the related art.

An advantage of the invention is to provide an increased sensitivity to flaw detection as compared to the conventional flaw detection and eddy current detection systems.

Another advantage of the invention is to provide better lift-off performance than with conventional detection system probes.

Additional features and advantages of the invention will be set forth in the description which follows, and in part will be apparent from the description, or may be learned by practice of the invention. These features and other advantages of the invention will be realized and attained by the structure particularly pointed out in the written description and claims hereof as well as the appended drawings. It is understood that the examples set forth herein are given by way of illustration and are not meant to limit the disclosure or the claims to follow.

To achieve these features and other advantages and in accordance with the purpose of the invention, as embodied and broadly described, a detection system, includes an eddy current inducing unit and at least one magnetic field data sensor electrically coupled to a biasing unit. The biasing unit is adapted to maintain the at least one magnetic field data sensor within a predetermined operating range when applied to a selected location of a workpiece as a function of residual magnetic field of the workpiece and the detection system also includes a scanner to position the at least one magnetic field data sensor at the selected locations on the workpiece at various resolutions.

Another aspect of the invention relates to a process for gathering data relating to an area of interest in a material. The process includes inducing an eddy current into the material with an eddy current inducing unit and measuring magnetic field data of the eddy currents induced in the material with at least one magnetic field data sensor at selected locations on the material. The process also includes biasing the magnetic field data sensor with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range. In addition, the process includes recording the measured magnetic field data and the measured amount required to bias the magnetic field data sensor at the selected locations.

A further aspect of the invention relates to a process for gathering data relating to an area of interest in a material. This process includes measuring the magnetic field of a material with at least one magnetic field data sensor at a selected location on the material. In addition, the process includes biasing the magnetic field data sensor with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range. The process includes recording the measured amount required to bias the magnetic field data sensor at the selected locations.

Another aspect of the invention relates to a method for identifying an area of interest in a material. The method includes measuring with at least one magnetic field data sensor a calibration block standard composed of the same type of material as a workpiece to be examined and having known areas of interest. Also, the method includes measuring the material with a magnetic field data sensor to obtain magnetic field data at selected locations on the material and biasing the magnetic field data sensor with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range. The process includes recording the amount required to bias the magnetic field data sensor, the measured magnetic field data of the material, and the measured magnetic field data of the calibration block standard. The differences and similarities are noted between the amount required to bias the magnetic field data sensor, the measured magnetic field data of the material, and the measured magnetic field data of the calibration block standard obtained at each of the selected locations on the material.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, are included to provide a further understanding of the invention and are incorporated in and constitute a part of this specification, illustrate embodiments of the invention and together with the description serve to explain aspects of the invention.

In the drawings:

FIG. 1A shows a typical response curve for a GMR sensor according to an aspect of the invention.

FIG. 1B shows a typical response curve for a SDT sensor according to another aspect of the invention.

FIG. 2 shows a single channel data acquisition system according to another aspect of the invention.

FIG. 3 shows a perspective view of a “T” shaped flexible printed circuit board according to another aspect of the invention.

FIG. 4A shows a top down view of a blade probe according to another aspect of the invention.

FIG. 4B shows a bottom up view of the blade probe of FIG. 4A.

FIG. 4C shows a side view of the blade probe of FIG. 4A.

FIG. 5A shows a profile view of a J-Groove weld probe apparatus according to another aspect of the invention.

FIG. 5B shows a blow-up view of a portion of the J-Groove weld probe apparatus according to FIG. 5A.

FIG. 6 shows a mock-up of an Inconel 600 CEDM nozzle according to an example of the invention.

FIG. 7 shows an operation example according to a method of the invention for inspecting the mock-up unit of FIG. 6.

### DETAILED DESCRIPTION OF THE ILLUSTRATED EMBODIMENTS

In one embodiment, the invention is directed towards a detection system including an eddy current inducing unit, at least one magnetic field data sensor, and a scanner. The detection system can accommodate the incorporation of one or more sensors. The eddy current inducing unit is an excitation element which can be arranged into various geometries as known in the art for inducing eddy currents into a material. For example, the excitation element may be an excitation coil arranged in a spiral trace to induce eddy currents into a material to be tested. An eddy current is a circular oscillating current induced with a eddy current inducing unit into the surface of a conductive or ferromagnetic component.

The magnetic field data sensor may be any sensor that responds to a change in a magnetic field as known in the art. A magnetic field is defined as either the applied or fluxed field within and surrounding either a magnetized part or a current-carrying conductor in which a magnetic force is exerted. For example, the sensor may be a giant magneto resistive (GMR) sensor, spin dependent tunneling (SDT) sensor, hall effect probe, and the like. Also, the magnetic field data sensor is electrically coupled to a biasing unit. The biasing unit is adapted to maintain the magnetic field data sensor within a predetermined operating range when applied to selected locations of a workpiece as a function of residual magnetic field of the workpiece. The residual magnetic field is the flux field that remains in a ferromagnetic specimen after an applied magnetic field removal. The operating range of a sensor is the range between cutoff and saturation of the magnetic field data sensor.

More specifically, in a preferred embodiment the biasing unit outputs a signal in response to a change in the residual magnetic field of the workpiece detected by the magnetic field data sensor. The output signal is input into an amplifier that is electrically coupled to the magnetic field data sensor. The amplifier outputs a voltage or current to a bias strap electrically coupled to the magnetic field data sensor in response the residual magnetic field detected by the magnetic field data sensor. The amplifier output increases or decreases the residual magnetic field detected by the sensor as is necessary thereby allowing the sensor to stay within the predetermined operating range. The bias strap may be constructed from materials known in the art, for example, copper, gold, alloys, and the like.

The detection system further includes a scanner to position the magnetic field data sensor at selected locations on the workpiece at various resolutions. The scanner is capable of moving the sensor to selected locations on the workpiece. There are a number of scanners commercially available, which may be utilized with the system. In a preferred embodiment, the sensor electronics are independent of the other components of the detection system. The scanning techniques are well known in the art. The system may also include a positional recorder for storing positional data at various scanner resolutions. The scanner resolution is the distance between data collection points. Commercially available positional recorders may be used as known in the art. In addition, the system may use a computer to process the positional data into respective positional x-y-z coordinates, as known in the art.

The detection system also may include a data recorder capable of recording data from the magnetic field data sensor at predetermined locations on the workpiece. The data recorder may be selected from commercially available recorders as known in the art.

The system may operate in an active mode or a passive mode. In an active mode eddy currents are induced into the material via the eddy current inducing unit and the detection system is operated. In a passive mode the detection system is operated while no eddy currents are induced into the material.

The detection system may also include a lock-in-amplifier electrically coupled to the magnetic field data sensor capable of processing generated magnetic field data into x-in-phase and y-quadature data. Eddy current data can be expressed as x-in-phase and y-quadature data, as is known in the art. The eddy current signature of a calibration block or standard material can be determined by methods known in the art. The eddy current signature of the material under inspection can then be compared with the standard eddy current signature to determine areas of interest.

In addition, the system may include a bias recorder electrically coupled to the biasing unit capable of recording the amount of voltage or current sent to a bias strap coupled to the magnetic field data sensor to maintain the magnetic field data sensor within a predetermined operating range as a function of the residual magnetic field of the workpiece. The voltage or current biasing amount is processed into a gauss unit. The gauss unit generated in the passive mode at a selected location can be compared with a gauss unit generated in the active mode at the same location of the workpiece. A difference may be indicative of an area of interest in the material and may indicate a location that was degaussed during the active mode.

Magnetic field data includes data that can be expressed as x-in-phase and y-quadature data, as is known in the art and residual magnetic field data that can be expressed in gauss units, as is known in the art.

In one embodiment, the invention is related to a process in the active mode for gathering data relating to an area of interest in a material. An area of interest is a discontinuity in a material, such as, a flaw, or stress, other anomaly as known in the art. For example, the area of interest may be an axial defect, circumferential defect, and/or transverse defect in a materials surface and/or within the materials volume. The area of interest may be the result of stress, plating, exposure to excessive temperatures, and/or corrosion on a material surface and/or within the material volume. The detection of stress in a location may develop into a future flaw.

The process includes inducing an eddy current into the material with an eddy current inducing unit. Magnetic field data of the eddy currents induced in the material with a magnetic field data sensor is measured at selected locations on the material. The measured magnetic field data includes raw data which is convertible into x-in-phase and y-quadature data. This data can be used to determine the eddy current signature of the material.

During operation the magnetic field data sensor is biased with a biasing unit to maintain the magnetic field data sensor within a predetermined operating range as a function of residual magnetic field of the material. The amount required to bias the magnetic field data sensor to maintain the magnetic field data sensor within the predetermined operating range is measured and recorded at selected locations on the material. The measured amount required to bias the magnetic field data sensor includes raw data which is convertible into a gauss unit. The selected locations where each of the data is measured are convertible into respective positional x-y-z coordinates, which can be plotted as known in the art.

In a further embodiment, the invention is related to a process for gathering data relating to an area of interest in a material. The process includes measuring the magnetic field of a material with a magnetic field data sensor, biasing the magnetic field data sensor, and recording the data. In such a process, the data is obtained in the passive mode of the detection system. More specifically, the magnetic field data of the material is measured at selected locations on the material.

Biasing the magnetic field data sensor includes biasing with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range. The measured amount required to bias the magnetic field data sensor includes raw data which is convertible into a gauss unit. The selected locations in which data is collected are convertible into respective positional x-y-z coordinates. Recording includes recording the measured amount required to bias the magnetic field data sensor at the selected locations. In this embodiment, the measured amount required to bias the magnetic field data sensor is obtained in the passive mode without inducing eddy currents in the material. This data can be used to determine areas of interest that may have been masked during data collection taken in the active mode.

In another embodiment, the invention relates to a method for identifying an area of interest in a material which includes measuring a calibration block standard with a magnetic field data sensor. Typically, the system instrumentation is initially calibrated in a conventional zero gauss chamber as known in the art. A calibration block, known in the art, which is made of the same type of material as the workpiece to be inspected and including known areas of interest, such as flaws of known length, depth and width, is scanned in the gauss chamber to obtain background data and data representative of the known areas of interest. This data includes magnetic filed data, which can be expressed as x-in-phase and y-quadature data and residual magnetic field data, which can be expressed in gauss units. The material is measured with a magnetic field data sensor to obtain magnetic field data at selected locations on the calibration block. During this measurement, the magnetic field data sensor is biased with a biasing unit to maintain the magnetic field data sensor within a predetermined operating range as a function of residual magnetic field. The amount required to bias the magnetic field data sensor to maintain the magnetic field data sensor within the predetermined operating range is measured at selected locations.

In one embodiment, the invention includes a method for identifying areas of interest in a material. The data generated from operating the detecting system in an active mode includes magnetic filed data, which can be expressed as x-in-phase and y-quadature data and residual magnetic field data, which can be expressed in gauss, which are collected at selected locations on the material. Data is also generated from operating the detecting system in a passive mode, which includes further residual magnetic field data, which can be expressed in gauss units, collected at selected locations on the material. Recording is performed with a recorder to record the amount required to bias the magnetic field data sensor in both the active mode and passive mode, the measured magnetic field data of the material, and the measured magnetic field data of the calibration block standard. The differences and similarities between the amount required to bias the magnetic field data sensor, the measured magnetic field data of the material, and the measured magnetic field data of the calibration block standard obtained at each of the selected locations on the material is noted and analyzed to determine whether there is an area of interest.

The calibration block magnetic field data, which can be expressed as x-in-phase and y-quadature data, is compared to the magnetic field data generated in the active mode, which can also be expressed as x-in-phase and y-quadature data of the material to determine similarities between the eddy current signature of the known areas of interest on the calibration block and the eddy current signature of the material, which may indicate areas of interest in the material. Correspondence with a magnetic signature, expressed as a change in a gauss unit reading at the same location (generated in either the active or passive mode) may indicate the age of the area of interest. A magnetic signature at a certain location of the material without the detection of an eddy current signature of an area of interest at that location may indicate, for example, an area under stress. The area under stress may have the potential for a future flaw.

Reference will now be made in detail to embodiments of the present invention, examples of which are illustrated in the accompanying drawings.

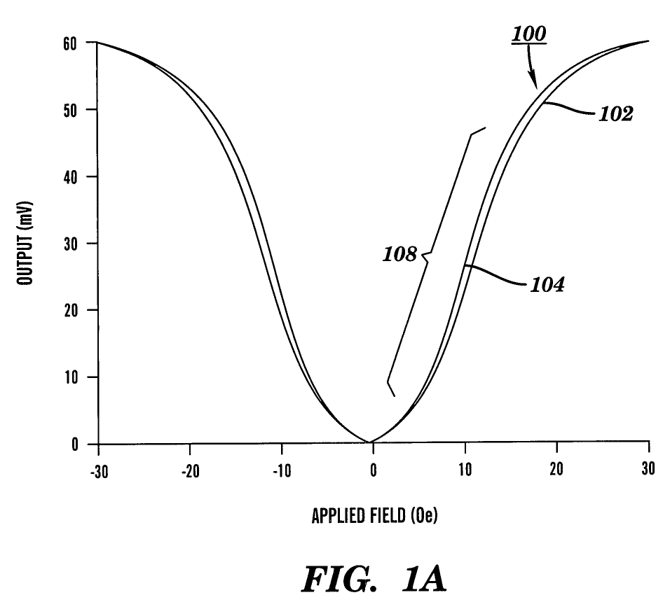

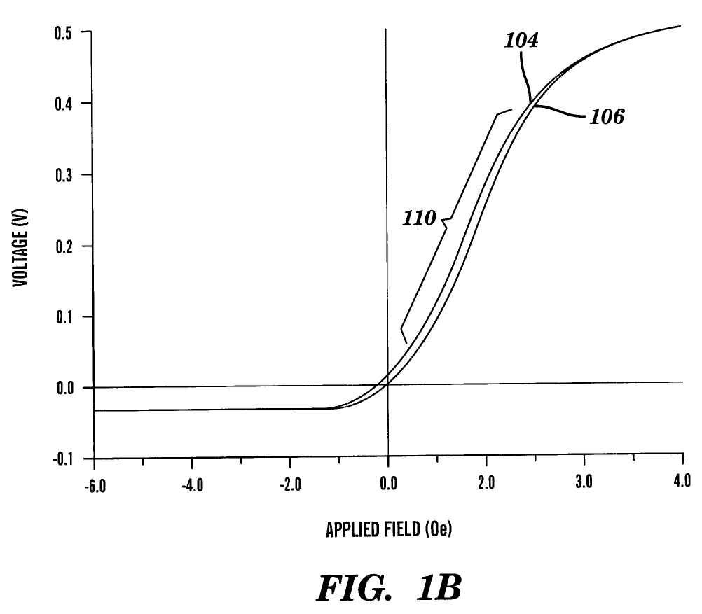

FIG. 1A shows a typical response curve for a GMR sensor. FIG. 1B shows a typical response curve for a SDT sensor.

FIGS. 1A and 1B illustrate response curves for GMR and SDT sensors as a change in their electrical resistance in response to applied magnetic fields. These sensors are configured as a bridge of resistors so that, when energized with for example, a DC supply voltage, they generate an output voltage that varies in response to an applied magnetic field. Referring to FIG. 1A the GMR response curve 100 illustrates the relationship between an applied magnetic field in Gauss (Oe) and an output of the sensor in millivolts (mV). The response curve of the GMR sensor is not linear and exhibits hysteresis 102. The hysteresis 102 is a response that follows a somewhat different curve depending on whether the applied magnetic field is increasing or decreasing. Referring to FIG. 1B the response curve of the SDT sensor 104 is not linear and also exhibits hysteresis 106. It was found that the GMR sensor as compared to an SDT exhibits somewhat more hysteresis. It was also found that the response curve between different GMR sensors was different. For example, the slope of the response curve was different and had different sensitivities and degrees of hysteresis.

Because of the residual magnetic field, a DC bias magnetic field is provided to the GMR and SDT sensors in order to achieve operation in the linear region of the curve. For example, these regions can be expressed as region 108 of FIG. 1A of the GMR sensor and region 110 of FIG. 1B of the SDT sensor. These represent the operating range of the sensor, which is the detection range between cutoff and saturation of the sensor. In principle, this bias field could be constant; however, the presence of existing magnetic fields will bias the operating point to regions that have different degrees of linearity, which will cause significant drift or noise in the eddy current response. In addition, if the existing fields are strong enough to move the response to a nonlinear region, then the field can no longer be measured accurately. To overcome these problems, a variable bias field is used. The bias is controlled to keep the sensor at a given operating point regardless of changes in the existing fields of the material under inspection. This is done by monitoring the sensor output and changing the bias field using a biasing unit (e.g., a feedback circuit), so that the field experienced by the sensor remains constant. The bias field can be generated by a DC current applied to a conductor placed near the sensor.

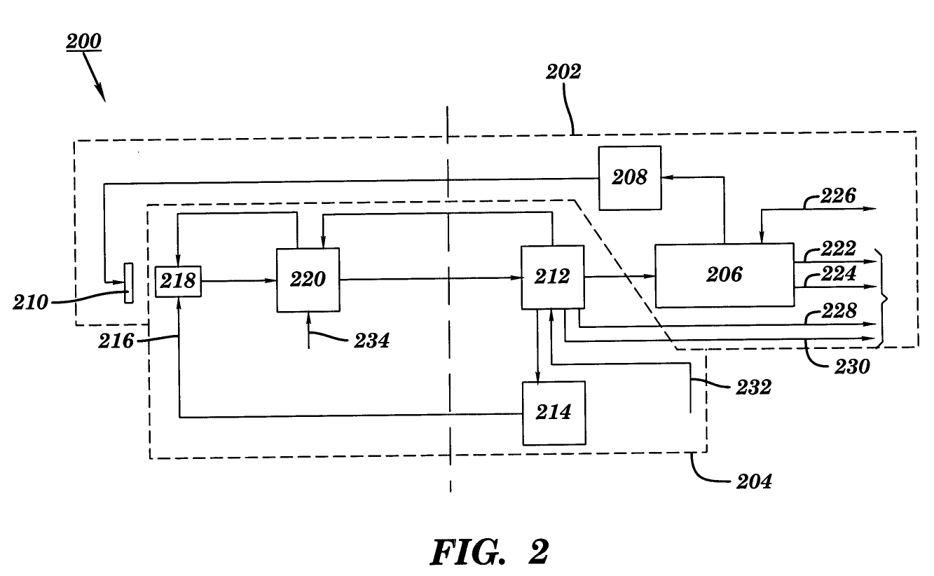

FIG. 2 shows a single channel data acquisition system according to an aspect of the invention. Referring to FIG. 2, the single channel data acquisition is represented as reference number 200 and includes an AC component 202 and a DC component 204. The AC component 202 includes a lock-in-amplifier 206 electrically coupled to a power amplifier 208 and electrically coupled to an eddy current inducing unit 210. A lock-in-amplifier is a signal recovery digital processor having inputs and outputs. Suitable lock-in-amplifiers include signal recovery model 7280. The lock-in-amplifier 208 may be any type of digital or analog signal processor having inputs and outputs as known in the art. The DC component 204 includes an automatic gain circuit 212, current or voltage amplifier 214, bias control strap 216, magnetic field data sensor 218, and preamplifier 220. On the automatic gain circuit 212, there is an input 232 used to calibrate the system. On the preamplifier 220 there is another input 234 which is also used to calibrate the system. Also, there is an magnetic field output 228 and a preamp output 230 from the automatic gain circuit 212.

Before operation a set-up procedure is conducted in a zero gauss chamber or known applied magnetic field (not shown) in order to calibrate the system. During this procedure the inputs 232 and 234 are adjusted in order to balance the circuit by ensuring the operating range of the response curve is in the desired location. More specifically, when using the GMR sensor as illustrated in FIG. 1B the goal is preferably to operate in the center of the operating range, e.g., linear region of the response curve of the sensor. For example, in this FIG. 1B a target calibration would be about 22.5 mV and about 9 gauss as shown in as reference number 104.

In operation of the channel data acquisition system, the DC component 202 controls the biasing based on residual magnetic field to keep the magnetic field data 218 sensor within its predetermined operation range. More specifically, the magnetic field data sensor 218 outputs a signal to the preamplifier 220. The preamplifier 220 amplifies the signal and outputs the amplified signal to the automatic gain control circuit 212. The automatic gain circuit 212 compares the amplified signal to a preset signal. Based on the results of the comparison an output signal is sent to a current amplifier 214 to increase or decrease current sent from the current amplifier 214 to the bias strap 216 in order to maintain the operation of the magnetic field data sensor within the operating range.

The AC component 202 controls frequency and voltage sent to the eddy current inducing unit 210 as is known in the art. For example, in this configuration, a lock-in amplifier 206 generates an AC signal at a desired frequency, the signal is sent to a power amplifier 208 and this signal is amplified by a power amplifier 208 and used to drive the eddy current inducing unit 210 as known in the art. The desired frequency range is chosen by the operator. The frequency is chosen by the operator based on material to be analyzed as known in the art. The lock-in amplifier 206 generates an x-value (in-phase) 222 and y-value (quadature) 224 signals. These are generated by the lock-in amplifier as known in the art. The lock-in amplifier can be controlled remotely by an interface 226 (e.g., RS232 or GPIB) as known in the art.

The single channel data acquisition is repeated as the number of sensors is increased in a one to one relationship. The detection system can accommodate one or more sensors as is desired. For example, when a three sensor array (3-channel system) is being utilized then three separated systems are utilized. That is, a three-channel circuit is used to control the magnetic bias field at each sensor (based on monitoring the sensor output) has been designed and fabricated. This circuit has the capability for adjusting the bias level remotely for each channel by means of DC inputs. The circuit may be built into a single rack-mount box. The circuit may utilize three analog-controllable, commercially available power supplies.

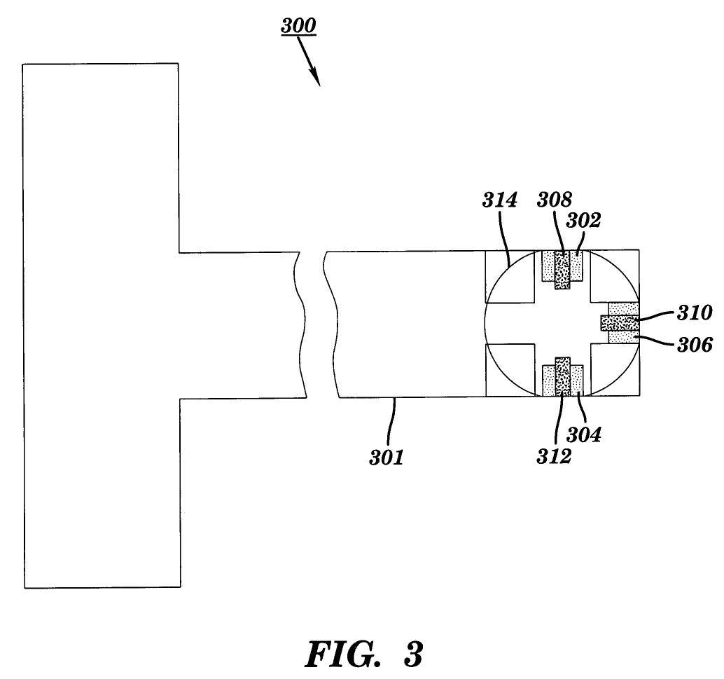

FIG. 3 is illustrates a three sensor system according to an aspect of the invention. In this configuration a “T” shaped flexible printed circuit (PC) board is used as represented by reference number 300. Three sensors 302, 304, and 306 are arranged and bonded to a flexible PC board 301. Three separate bias straps 308, 310, and 312, were electrically coupled to the each of the three sensors 302, 306, and 304, respectively. In a preferred embodiment, the bias strap is arranged substantially orthogonal to the sensing orientation of the magnetic field data sensor. However, the bias strap orientation can be configured in any manner as is desired to influence the magnetic field detected by the sensor. The sensors are arranged under the footprint 314 of the excitation coil (not shown) and the footprint 314 of the excitation coil in this embodiment is about ¼ inch circle of the coil. Any type of flexible substrate or traditional substrates may be utilized, for example, a plastic substrate, glass substrate, and the like. The “T” shaped flexible printed circuit board may be used with any number of different probes.

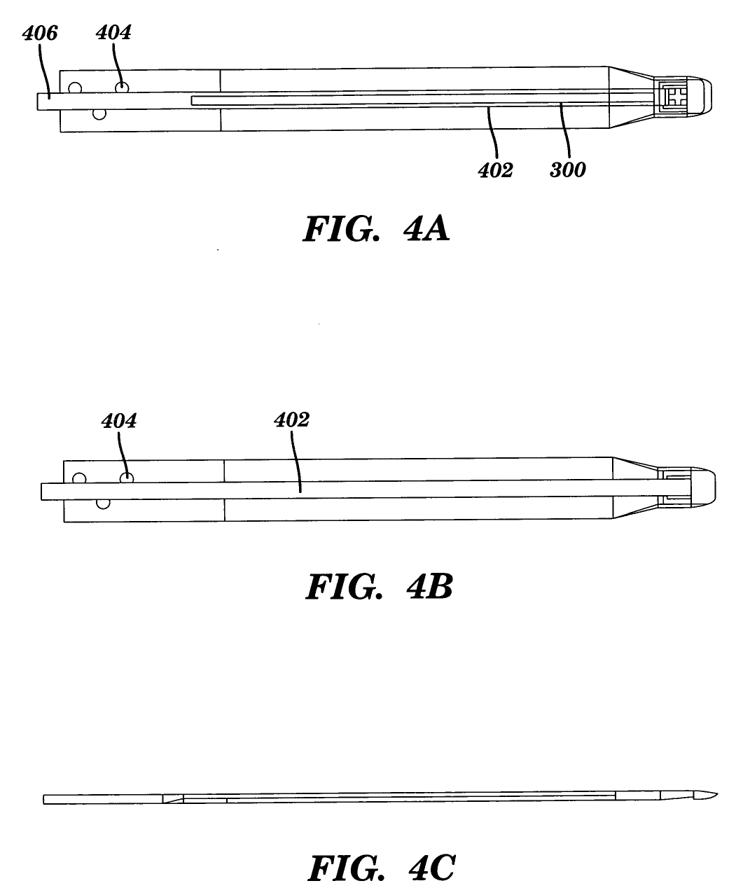

FIG. 4A shows a top down view of a blade probe according to another aspect of the invention. FIG. 4B shows a bottom up view of the blade probe of FIG. 4A. FIG. 4C shows a side view of the blade probe of FIG. 4A.

Referring to FIGS. 4A-4C, the blade probe has been developed for inspection of narrow spaces. More specifically, the blade probe allows for access to narrow gaps-while maintaining contact to the material surface during the scan. In this embodiment, the “T” shaped flexible printed circuit (PC) board 300 with three sensors as described in FIG. 3 was arranged into the blade probe. The blade probe can access gaps of about 0.076 inches or smaller. The thickness of the blade probe may be about 50-thousandths of an inch or less. Also, it can be formed to various radii of the desired item to be measured. For example, it may be formed to have a radius of penetration and may have varying thickness from edge to edge to assist in maintaining contact to the surface of the material to be tested.

The blade probe may be fabricated from plastic material, for example, ABS plastic, and the sensor boards shown in FIGS. 4A-4C, along with an excitation coil board that will be designed and fabricated, and are arranged inside the probe body. The leads for each probe may be configured in one or two pigtails of about 2 feet that terminate in connectors 406. The blade probes have cutouts 402 where the PCB is arranged. The blade probe in this embodiment is designed to have a similar radius of the material to be inspected. The blade probe has support holes 404 for mounting to an external positioning apparatus as known in the art. In operation, this design forces the center point of the probe, or the tip, to make contact with the material to be scanned.

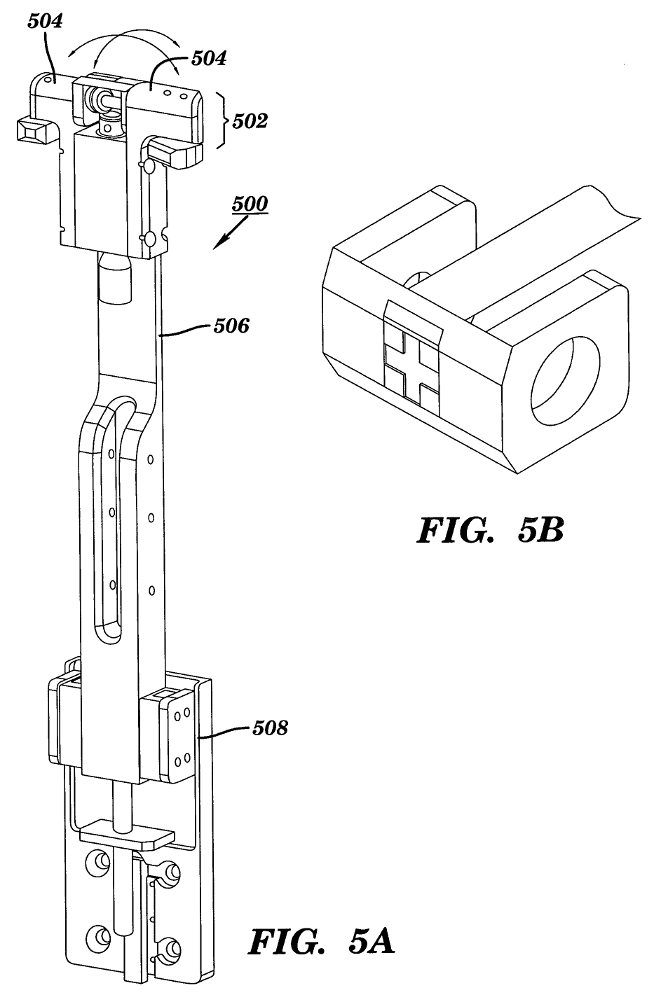

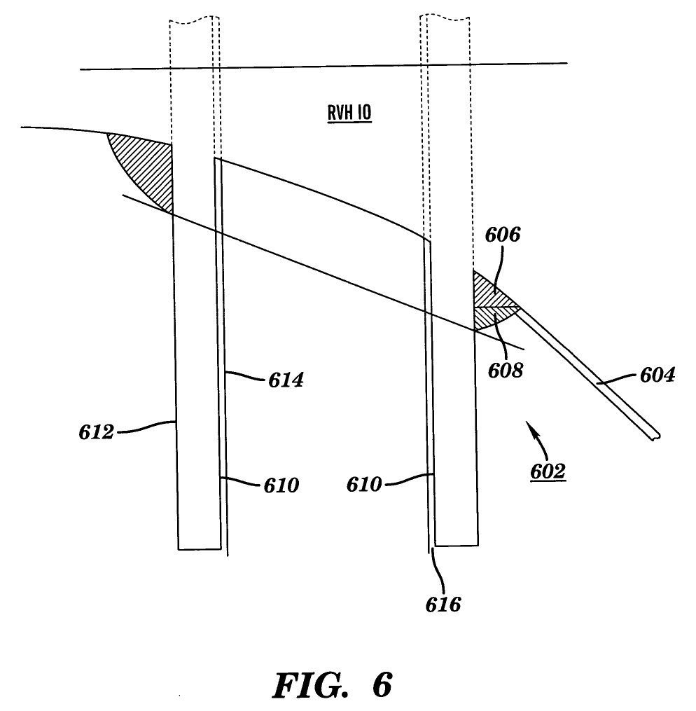

FIG. 5A shows a profile view of a J-Groove weld probe apparatus according to another aspect of the invention. FIG. 5B shows a blow-up view of a head portion of the J-Groove weld probe according to FIG. 5A.

Referring to FIGS. 5A and 5B, the J-Groove weld probe apparatus is represented as reference number 500. The apparatus includes wings 504 extending from either side of a top portion, a body portion 506, and a mounting portion 508. The apparatus is capable of being mounted on a positional system with the mounting portion 508 as known in the art. The J-Groove weld probe head 502 is rockable during use as indicated the arrows and allows for data collection of complex geometries, such as allowing for data collection of a nuclear reactor head to penetration of a J-Groove weld. For example, for inspection of the nozzle OD and the J-groove weld a probe can be adjusted to variable angles. The arrangement of sensors shown in FIG. 3 were arranged into housings of the J-Groove Weld probes. The probe configuration is shown in FIG. 5B. These probes use the same sensors as shown in FIG. 5B.

The apparatus 500 has the ability to change its orientation angle to the penetration. For example, from a standpoint of an inverted bowl with an array of tubes coming through that bowl a concave configuration is present. This J-groove apparatus allows for an accurate measurement of a concave geometric configuration of a material to be tested and also allows for various measurements at various orientation angles of penetration. For example, if the penetration are perpendicular there are various angles to accommodate in the measurement. Therefore, this particular apparatus head 502 was designed to rotate at different angles.

A typical scan procedure is designed to perform a circumferential scan and a cylindrical scan around the head and then increment the radius and repeat, until concluding at the concave portion of the head. In a preferred scan configuration for this type of design, the apparatus performing the scan is configured to rotate plus or minus 5 degrees in either direction, for example, from lift-off to lift-off, in a circumferential motion. Thus, scanning and rotating in a cylindrical pattern while rocking the head 5 degrees in each pass or each 60-thousandths (e.g., plus or minus 2.5 degrees) from lift-off to lift-off. This scanning method is conducted around material until all the area has been inspected. Another preferred method is to move the probe head simultaneously in an axial, head tip, and radial increment motions, which is based on a derived vector of the orientation angle and current penetration location in degrees. When the vector motion is completed the head tip is returned to its start position, the circumferential motion is incremented and a new vector is executed. This cycle is repeated until the full coverage has been met. Preferably, the head tip motion is +−95 degrees. After completion, the scan is incremented along the radius and repeated. Accordingly, a complete scan coverage can be obtained and lift-off problems are substantially eliminated. Additionally, a greater coverage is possible as compared to circumferential and cylindrical scans, thereby permitting determination of where a flaw actually occurred or where the flaw is located. Moreover, the configuration allows for scanning extremely small geometries.

### EXAMPLE

In this example a mock-up of a nuclear reactor head design was fabricated for testing. The mock-up includes an Inconel 600 control element drive mechanism (CEDM) nozzle inside a reactor vessel head which was analyzed. The CEDM nozzle was inserted in the reactor head 602 having a 308 stainless steel cladding layer 604 and welded in a J-groove configuration with A82 filler metal 606 and A182 filler metal 608. The nozzle has an inside diameter 610 and outside diameter 612 and was constructed from Inconel 600 material. A thermal sleeve 614 is arranged inside the nozzle creating a small gap 616 of about 0.073 inches, thereby obstructing measurement of the inside diameter with conventional eddy current probes. Additionally, the mock-up included surface flaws that were formed into the A182 filler material as indicated in Table 2, described below. These flaws were then visually concealed with techniques known in the art.

In this example, we utilized a blade probe holder to collect data on the inside diameter and outside diameter of the CEDM nozzle. A J-groove probe holder was utilized to collect data from the outside diameter through the J-groove A82 filler metal and A182 filler metal to the cladding.

Three GMR sensors were arranged as illustrated in FIGS. 3, 5A, and 5B. A single channel data acquisition systems was utilized for each magnetic field sensor (i.e., a three-channel system). The GMR sensors were set-up by placing a zero gauss chamber over the GMR sensor array of FIG. 3. The pre-amplifier and magnetic field offset value were balanced as discussed above with reference to FIG. 2. The calibration block was installed in the scanner and the gauss chamber was reinstalled to acquire a baseline. The calibration block included electro discharge machine (EDM) notches at different depths, lengths, and widths. Table 1 shows detailed data collected during the calibration block set-up to generate a calibration curve.

TABLE 1

| | | Calculated | |
|---|---|---|---|
| | Phase Shift | Standard Depth | |
| Notch Depths | Based on Notch | of Penetration | Percent Screen |
| (Inches) | Depth (degrees) | (Inches) | Height |
| 0.008 | 13.8 | 0.033 (1 SDP) | 5.0 |
| 0.02 | 34.7 | 0.067 (2 SDP) | 16.7 |
| 0.04 | 68.4 | 0.1 (3 SDP) | 25.0 |

In Table 1, the phase shift based on notch depth was calculated assuming 1 radian in phase shift per 1 standard depth of penetration as known in the art. The standard depth of penetration was calculated based upon the eddy current standard depth of penetration formula as known in the art. More specifically, the standard depth of penetration may be calculated when the material resistivity (ohms*meter), desired frequency (hertz), and material permeability (H/m) are known. The percent screen height is collected as known in the art. From Table 1 a calibration curve may be made having on the x-axis crack depth and on the y-axis percent inductive reactance as known in art.

After generating the calibrating curve the mock-up of a nuclear reactor head was tested. The blade probe holder was then used to collect data on the inside diameter and outside diameter of the CEDM nozzle according to the methods of the present invention. Next, a J-groove scan was conducted to collect data from the outside diameter through the J-groove A82 filler metal and A182 filler metal to the cladding. The data from the J-groove scan is shown table 2 and FIG. 10.

TABLE 2

| | | Length of the | Depth of the |
|---|---|---|---|
| Flaw | Orientation of the Flaw | Flaw (mils) | Flaw (mils) |
| 1. | Axial | 135 | 40 |
| 2. | Axial | 125 | 20 |
| 3. | Axial | 90 | 80 |
| 4. | Circumferential | 125 | 20 |
| 5. | Circumferential | 90 | 80 |

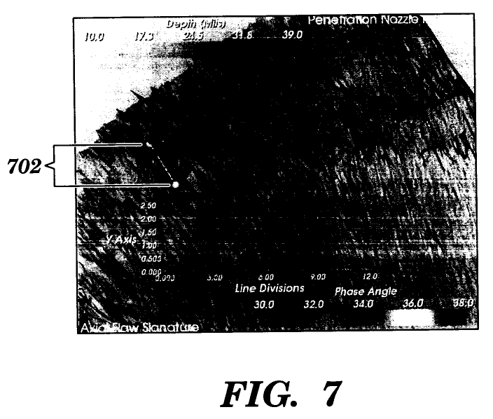

During scanning with the J-Groove Weld probe flaws 1-5 as shown in Table 2 were all detected. FIG. 7 represents a two-dimensional contour map as represented as reference number f the residual magnetic field data collected on the mock-up unit of flaw 1 of Table 2. The flaw is graphically represented as area 702.

While the invention has been described with preferred embodiments, it is to be understood that variations and modifications are to be considered within the purview and the scope of the claims appended hereto.

What is claimed:

1. A detection system, comprising:
an eddy current inducing unit;
at least one magnetic field data sensor electrically coupled to a biasing unit, wherein the biasing unit is adapted to maintain the at least one magnetic field data sensor within a predetermined operating range when applied to selected locations of a workpiece as a function of residual magnetic field of the workpiece; and
a scanner to position the at least one magnetic field data sensor at the selected locations on the workpiece at various resolutions.

2. The detection system of claim 1, wherein the biasing unit outputs a signal in response to a change in the residual magnetic field of the workpiece detected by the at least one magnetic field data sensor, wherein the signal is input into an amplifier and the amplifier is electrically coupled to the at least one magnetic field data sensor.

3. The detection system of claim 2, wherein the amplifier outputs a voltage or current to a bias strap electrically coupled to the at least one magnetic field data sensor in response the residual magnetic field detected by the at least one magnetic filed data sensor.

4. The detection system of claim 1, further comprising a data recorder capable of recording data from the at least one magnetic field data sensor at the selected locations on the workpiece.

5. The detection system of claim 1, wherein the at least one magnetic field data sensor comprises at least one of giant magneto resistive sensor, spin dependent tunneling sensor, and hall effect probe.

6. The detection system of claim 1, wherein the detection system operates in an active mode or a passive mode.

7. The detection system of claim 6, wherein the at least one magnetic field data sensor generates magnetic field data from eddy currents induced in a workpiece while the system is operating in the active mode.

8. The detection system of claim 7, further comprising a lock-in-amplifier electrically coupled to the at least one magnetic field data sensor capable of processing the generated magnetic field data into x-in-phase and y-quadature data.

9. The detection system of claim 1, further comprising a bias recorder electrically coupled to the biasing unit capable of recording the amount of voltage or current sent to a bias strap coupled the at least one magnetic field data sensor to maintain the at least one magnetic field data sensor within a predetermined operating range as a function of the residual magnetic field of the workpiece.

10. The detection system of claim 9, wherein the voltage or current amount is processed into a gauss unit.

11. The detection system of claim 1, further comprising a positional recorder for storing positional data at various scanner resolutions.

12. The detection system of claim 11, further comprising:
a computer for processing the positional data into respective positional x-y-z coordinates.

13. A process for gathering data relating to an area of interest in a material, comprising:
inducing an eddy current into the material with an eddy current inducing unit;
measuring magnetic field data of the eddy currents induced in the material with a magnetic field data sensor at selected locations on the material;
biasing the magnetic field data sensor with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range; and
recording the measured magnetic field data and the measured amount required to bias the magnetic field data sensor at the selected locations.

14. The process of claim 13, wherein the measured magnetic field data comprises
raw data which is convertible into x-in-phase and y-quadature data.

15. The process of claim 13, wherein the measured amount required to bias the magnetic field data sensor comprises raw data which is convertible into a guass value.

16. The process of claim 13, wherein the selected locations are convertible into respective positional x-y-z coordinates.

17. A process for gathering data relating to an area of interest in a material, comprising:
measuring the magnetic field of a material with a magnetic field data sensor at a selected location on the material;
biasing the magnetic field data sensor with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range; and
recording the measured amount required to bias the magnetic field data sensor at the selected locations.

18. The process of claim 17, wherein the measured amount required to bias the magnetic field data sensor comprises raw data which is convertible into a guass value.

19. The process of claim 17, wherein the selected locations are convertible into respective positional x-y-z coordinates.

20. A method for identifying an area of interest in a material, comprising:
measuring with a magnetic field data sensor a calibration block standard comprising the same type of material as a workpiece to be examined and having know areas of interest;
measuring the material with a magnetic field data sensor to obtain magnetic field data at selected locations on the material;
biasing the magnetic field data sensor with a biasing unit to maintain the magnetic field data sensor within a predetermined operating range as a function of residual magnetic field of the material and measuring at selected locations on the material the amount required to bias the magnetic field data sensor to maintain the magnetic field data sensor within the predetermined operating range;
recording the amount required to bias the magnetic field data sensor, the measured magnetic field data of the material, and the measured magnetic field data of the calibration block standard; and
noting differences and similarities between the amount required to bias the magnetic field data sensor, the measured magnetic field data of the material, and the measured magnetic field data of the calibration block standard obtained at each of the selected locations on the material.
